(19) United States
(12) Patent Application Publication
(10) Pub. No.: US 2021/0159393 A1
(43) Pub. Date: May 27, 2021

(54) MAGNETIC TUNNEL JUNCTION DEVICES AND METHODS OF FORMING THEREOF

(71) Applicant: GLOBALFOUNDRIES Singapore Pte. Ltd., Singapore (SG)

(72) Inventors: Wai Cheung LAW, Singapore (SG); Ganesh KOLLIYIL RAJAN, Singapore (SG); Yuichi OTANI, Singapore (SG); Kazutaka YAMANE, Singapore (SG); Chim Seng SEET, Singapore (SG); Grayson Dao Hwee WONG, Singapore (SG)

(21) Appl. No.: 16/695,333

(22) Filed: Nov. 26, 2019

(51) Int. Cl. H01L 43/02; H01L 43/12; H01L 43/10; H01F 10/32

(52) U.S. Cl. CPC H01L 43/02; H01L 43/12; H01F 10/329; H01F 10/3254; H01L 43/10

(57) ABSTRACT

In a non-limiting embodiment, a semiconductor device may include a magnetic tunnel junction (MTJ) stack. The MTJ stack may include a reference layer comprising a magnetic layer, a first tunneling barrier layer arranged over the reference layer, a free layer comprising a magnetic layer arranged over the first tunneling barrier layer, and a capping layer arranged over the reference layer, the first tunneling barrier layer and the free layer. The capping layer may be a non-magnetic layer. According to various non-limiting embodiments, the capping layer may include a rare earth element. According to various non-limiting embodiments, the MTJ stack may further include a second tunneling barrier layer arranged between the free layer and the capping layer. The capping layer may contact the second tunneling barrier layer.

### TECHNICAL FIELD

The present disclosure relates generally to semiconductor devices, and more particularly relates to magnetic tunnel junction (MTJ) devices and methods of forming MTJ devices.

### BACKGROUND

Magnetoresistive Random Access Memory (MRAM) is an emerging technology that may be competitive with prior integrated circuit memory technologies, such as floating gate technology. The MRAM technology, for example, may integrate silicon-based electronic components with magnetic tunnel junction (MTJ) technology. The MTJ is a significant element where information may be stored. An MTJ stack has at least two magnetic layers separated by a non-magnetic tunneling barrier layer. One of the magnetic layers may be a fixed layer which has a set magnetic property, while another one of the magnetic layers may be a free layer which has a programmable magnetic property for storing information. If the fixed layer and the free layer have parallel magnetic poles, the resistance through the MTJ stack is measurably less than if the fixed layer and the free layer have anti-parallel poles, so parallel magnetic poles may be read as a “0” and anti-parallel poles may be read as a “1.” The MTJ stack is typically incorporated into a memory cell, and many memory cells with MTJ stacks are incorporated into a memory bank.

The magnetic properties of the free layer may be changed when the memory cell is programmed, where the alignment of the magnetic properties of the free layer is changed relative to the magnetic properties of the fixed layer in the programming process. Programming changes the magnetic properties of the free layer and the fixed layer from anti-parallel to parallel, or from parallel to anti-parallel. A memory cell with high Tunnel Magnetoresistance (TMR) may have a high read-out signal, which may speed the reading of the memory cell during operation. High TMR may also enable use of low programming current. In order to achieve a high TMR ratio, the series resistance of the MTJ stack should be as low as possible. A low resistance can also reduce the amount of current required to induce magnetization reversal in the MTJ stack. For example, the spin polarizing efficiency of the reference/dielectric layer must be as high as possible to achieve a high TMR ratio. One may achieve high spin polarizing efficiency by increasing the thickness of the tunneling barrier layer, but at the expense of higher series resistance. For example, increasing the thickness of the tunneling barrier layer corresponds to an increase in the resistance of the MTJ, which will subsequently affect RC delay and the critical voltage, V_{c} to switch the magnetization direction.

From the foregoing discussion, it is desirable to provide improved MTJ devices having higher TMR and with reduced write current density.

### SUMMARY

Embodiments generally relate to semiconductor devices and methods for forming the semiconductor devices. According to various non-limiting embodiments, a semiconductor device may include a magnetic tunnel junction (MTJ) stack. The MTJ stack may include a reference layer comprising a magnetic layer, a first tunneling barrier layer arranged over the reference layer, a free layer comprising a magnetic layer arranged over the first tunneling barrier layer, and a capping layer arranged over the reference layer, the first tunneling barrier layer and the free layer. The capping layer may be a non-magnetic layer. According to various non-limiting embodiments, the capping layer may include a rare earth element. According to various non-limiting embodiments, the MTJ stack may further include a second tunneling barrier layer arranged between the free layer and the capping layer. The capping layer may contact the second tunneling barrier layer.

According to various non-limiting embodiments, a method of forming a MTJ stack is provided. The method may include forming a reference layer comprising a magnetic layer, forming a first tunneling barrier layer over the reference layer, forming a free layer comprising a magnetic layer over the first tunneling barrier layer, and forming a capping layer arranged over the reference layer, the first tunneling barrier layer and the free layer. The capping layer may be a non-magnetic layer, and includes a rare earth element. According to various non-limiting embodiments, the method may further include forming a second tunneling barrier layer between the free layer and the capping layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIGS. 1A-1D show simplified cross-sectional views of embodiments of a device;

FIGS. 2A-2C show simplified cross-sectional views of embodiments of the device in greater detail; and

FIGS. 3A-3B show simplified cross-sectional views of an embodiment of a process for forming a device.

### DETAILED DESCRIPTION

The following detailed description refers to the accompanying drawings that show, by way of illustration, specific details and embodiments in which the embodiments may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Embodiments of the present disclosure generally relate to semiconductor devices. The semiconductor devices may be, or include, magnetic tunnel junction (MTJ) devices. In various non-limiting embodiments, an MTJ device may include an MTJ stack. The MTJ stack may include a reference layer (or reference layer stack), a free layer (or free layer stack), and a first tunneling barrier layer arranged between the reference layer and the free layer. The reference layer and the free layer may each include at least one magnetic layer, while the first tunneling barrier layer may be a non-magnetic layer. The MTJ device may be a perpendicular MTJ (pMTJ) device, in a non-limiting embodiment.

A capping layer may be arranged over the reference layer, the first tunneling barrier layer and the free layer. The capping layer may be a non-magnetic layer. The capping layer may promote the magnetic anisotropic effect of the MTJ stack. According to various non-limiting embodiments, the capping layer may include a rare earth (or rare earth metal) element(s). The capping layer may be a conductive metal oxide layer formed from the rare earth element. According to various non-limiting embodiments, rare earth elements having high enthalpy of formation of sesquioxides may be chosen for forming the capping layer. The oxides of the rare earth metal chosen for forming the capping layer may have a higher electrical conductivity than the second tunneling barrier layer (e.g., MgO layer), thus reducing the resistive area (RA) while increasing the TMR. The electrical conductivity of the metal oxide forming the capping layer may be at least 5×10⁹ Ω⁻¹·cm⁻¹, in a non-limiting embodiment.

According to various non-limiting embodiments, the capping layer may include a rare earth element such as, but not limited to, lanthanum (La), praseodymium (Pr), neodymium (Nd), samarium (Sm), europium (Eu), gadolinium (Gd), holmium (Ho), or alloys thereof, and which may be present as a single layer or as multiple layers. In some embodiments, the capping layer may be a rare earth transition metal alloy. In a non-limiting example, transition metal which may be used to form the rare earth transition metal alloy for the capping layer may include scandium (Sc), titanium (Ti), vanadium (V), chromium (Cr), yttrium (Y), zirconium (Zr), hafnium (Hf), tantalum (Ta), tungsten (W), aluminium (Al), thallium (Tl).

According to various non-limiting embodiments, the first tunneling barrier layer may be arranged over the reference layer, and the free layer may be arranged over the first tunneling barrier layer.

According to various non-limiting embodiments, the MTJ stack may further include a second tunneling barrier layer arranged between the free layer and the capping layer. Accordingly, the free layer may be sandwiched between the first tunneling barrier layer and the second tunneling barrier layer. The second tunneling barrier layer may be arranged in the MTJ stack to promote the crystallinity and magnetic properties of free layer. The capping layer contacts the second tunneling barrier layer. According to various non-limiting embodiments, the capping layer is not alloyed with the second tunneling barrier layer of the MTJ stack, which advantageously enables the second tunneling barrier layer to retain its small lattice mismatch with the free layer (i.e., the interface between the second tunneling barrier layer and the free layer is not disturbed). Arranging the capping layer over the second tunneling barrier layer without alloying to the second tunneling barrier layer further facilitates quality or process control in the device fabrication. For example, there is no need for additional processing steps such as alloying the second tunneling barrier layer (e.g., MgO) which may increase variation, disrupt crystallinity, and increase lattice mismatch with the magnetic free layer (e.g., CoFeB).

The capping layer having the rare earth element according to various embodiments of the present invention serves as a protective barrier which restricts interlayer diffusion from the overlying electrode (e.g., top electrode) and advantageously protects and/or conserves the crystallinity of the second tunneling barrier layer. By ensuring the pristine condition of the second tunneling barrier layer, a high spin polarizing efficiency may be achieved for the MTJ stack. In various embodiments, the rare earth element used for forming the capping layer, such as Ho in a non-limiting example, has a high enthalpy of formation of oxide which may be used to tune the oxygen content in the tunneling barrier layer (e.g., second tunneling barrier layer). Control of the oxygen content in the tunneling barrier layer by the capping layer may be useful to prevent damage or degradation of magnetic performance of the free layer due to diffused oxygen (e.g., diffused oxygen due to high temperature processes performed during back-end-of-line (BEOL) processing). Otherwise, damage from the diffused oxygen may significantly increase the resistive area (RA) and degrade the magnetoresistance percentage (MR %) of the MTJ device or cell. Accordingly, the MTJ stack may be provided with an improved crystalline structure in the free layer. Further, the capping layer which includes metal oxide layer formed from the rare earth element has a high electrical conductivity which advantageously lowers the series resistance of the MTJ stack.

Accordingly, the capping layer having the rare earth metal element may be used for oxygen scavenging (or gettering) from the underlying second tunneling barrier layer and to control the stoichiometry of the second tunneling barrier layer, while concurrently increasing conductivity of the MTJ stack. The MTJ stack incorporating the capping layer according to various embodiments provides an MTJ cell with reduced or low RA and increased or high TMR ratio. Additionally, the current density required to perform a write operation may be reduced.

As used herein, a layer or material is “magnetic” if it is a ferromagnetic material, where the term “ferromagnetic” does not require the presence of iron. More particularly, a material is “magnetic” if it is a permanent magnet that retains its magnetic field after an induction magnetic field is removed, where the permanent magnet has a residual flux density of about 0.1 tesla or more, in a non-limiting example. A layer or material is “non-magnetic” if it is a diamagnetic or a paramagnetic material, and more particularly does not form a permanent magnet or is only capable of forming a permanent magnet that has a residual flux density of less than about 0.1 tesla or less, in a non-limiting example. In a non-limiting example, a “permanent” magnet is a magnet that has residual flux density of about 0.1 tesla or more for at least about 1 week or more after being removed from an induction magnetic field.

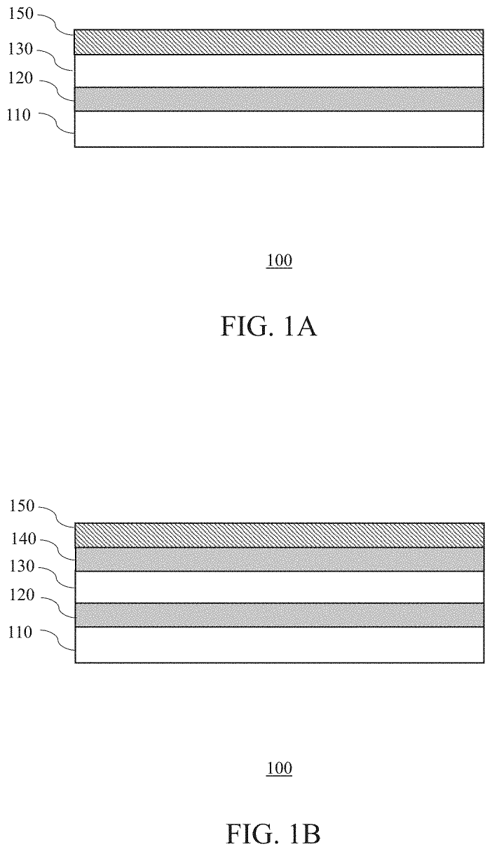

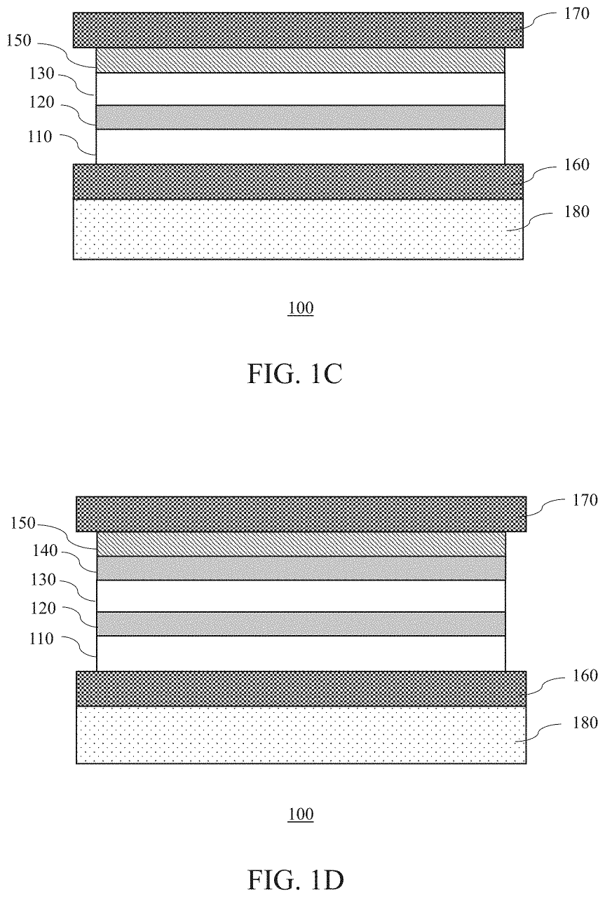

FIGS. 1A-1B show simplified cross-sectional views of embodiments of a device 100. The device 100 may be a semiconductor device. In various non-limiting embodiments, the device 100 may be, or include, a MTJ device or stack. The MTJ device may include a reference or fixed layer 110, a first tunneling barrier layer 120 and a free layer 130. As illustrated in FIGS. 1A and 1B, the first tunneling barrier layer 120 may be arranged over the reference layer 110, and the free layer 130 may be arranged over the first tunneling barrier layer 120. As described, the first tunneling barrier layer 120 may be non-magnetic, and magnetically decouples the free layer 130 from the reference layer 110.

The MTJ device may further include a capping layer 150 arranged over the reference layer 110, the first tunneling barrier layer 120 and the free layer 130. The capping layer may be non-magnetic (i.e., a non-magnetic layer). According to various non-limiting embodiments, the capping layer may include a rare earth element such as La, Pr, Nd, Sm, Eu, Gd, Ho, or alloys thereof, in a non-limiting example.

According to various non-limiting embodiments, the capping layer 150 may include the rare earth element in an amount ranging from about 30 to about 100 weight percent, based on a total weight of the capping layer. In a non-limiting embodiment, the composition of the capping layer 150 may be dependent on the material(s) of the second tunneling barrier layer 140 and/or the free layer 130.

According to various non-limiting embodiments, the capping layer 150 formed with the rare earth element may have a large grain size due to a lower melting point. Large grain sizes in the capping layer may result in fewer grain boundaries in which fast diffusion may occur. Accordingly, such capping layer reduces interlayer diffusion, for example, from an overlying top electrode.

In a non-limiting embodiment, the capping layer 150 may include Ho in an amount ranging from about 30 to about 100 weight percent, based on a total weight of the capping layer. In another non-limiting embodiment, the capping layer 150 may include Ho in an amount ranging from about 60 to about 100 weight percent, based on a total weight of the capping layer. In yet another non-limiting embodiment, the capping layer 150 may include Ho in an amount ranging from about 80 to about 100 weight percent, based on a total weight of the capping layer.

According to various non-limiting embodiments, the capping layer 150 may have a thickness of about 1.5 nm or less. In a non-limiting embodiment, the thickness of the capping layer 150 is not increased above a predetermined thickness which may otherwise adversely affect the stoichiometry of an underlying second tunneling barrier layer 140, as illustrated in FIG. 1B. The predetermined thickness may be about 1.5 nm, in a non-limiting example. Providing the capping layer 150 within the predetermined thickness in the MTJ stack ensures that the series resistance in the MTJ stack is not increased to an undesirable level, in order to increase or maintain a desired TMR of the MTJ stack.

In a non-limiting embodiment, the capping layer 150 may be, or include, a conductive metal oxide layer formed from the rare earth element. In some embodiments, the capping layer 150 may be a rare-earth transition metal alloy. The transition metal elements which may be used in the rare-earth transition metal alloy for the capping layer 150 may include Sc, Ti, V, Cr, Y, Zr, Hf, Ta, W, Al, Tl, or combinations thereof, in a non-limiting example.

According to various non-limiting embodiments, the MTJ device may further include the second tunneling barrier layer 140 arranged over the free layer 130, as illustrated in FIG. 1B. As illustrated, the free layer 130 may be sandwiched between two tunneling barrier layers (e.g., the first tunneling barrier layer 120 and the second tunneling barrier layer 140). The capping layer 150 may be arranged over the second tunneling barrier layer 140, and contacts the second tunneling barrier layer 140. A surface of the capping layer 150 interfaces a surface of the second tunneling barrier layer 140. For example, a bottom surface of the capping layer 150 interfaces a top surface of the second tunneling barrier layer 140. In a non-limiting example, in the case the thickness of the second tunneling barrier layer 140 (e.g., MgO) ranges from about 0.8 nm to about 2 nm, the thickness of the capping layer 150 may range from about 0.5 nm to about 1.5 nm.

According to various non-limiting embodiments, each of the first tunneling barrier layer 120 and the second tunneling barrier layer 140 may be, or include, a dielectric oxide layer. The first tunneling barrier layer 120 and/or the second tunneling barrier layer 140 may include magnesium oxide (MgO), in a non-limiting example. Other materials, such as aluminum oxide (AlO), suitable for a high TMR ratio, while magnetically decoupling the free layer from the reference layer by the first tunneling barrier layer, may also be used.

According to various non-limiting embodiments, the MTJ stack may be arranged between a first electrode 160 and a second electrode 170 of the device 100, as illustrated in FIGS. 1C-1D. For example, the first electrode 160 may be a bottom electrode, while the second electrode 170 may be a top electrode, where the MTJ stack is in electrical communication with the bottom and top electrodes. In a non-limiting embodiment, the capping layer 150 of the MTJ stack contacts the second electrode 170. The capping layer 150, which overlays the second tunneling barrier layer 140, serves as a protective barrier against the diffusion of the top electrode. Other configurations for the first electrode 160 and the second electrode 170 may also be used. As illustrated in FIG. 1D, the second electrode 170 overlies the capping layer 150, so the second electrode 170 also overlies the second tunneling barrier layer 140, the free layer 130, the first tunneling barrier layer 120, and the reference layer 110. The first electrode 160 and the second electrode 170 may include several layers (not illustrated), such as a seed layer, a core, and a cover, and may include tantalum (Ta), tantalum nitride (TaN), nickel (Ni), copper (Cu), aluminum (Al), or other electrically conductive materials.

As illustrated in FIGS. 1C-1D, the MTJ device may be arranged over a substrate 180. The substrate 180 may be a semiconductor substrate, such as a silicon substrate. The substrate 180 may be a bulk silicon wafer (as illustrated) or may be a thin layer of silicon on an insulating layer (commonly known as silicon-on-insulator or SOI, not illustrated) that, in turn, is supported by a carrier wafer. Other types of semiconductor substrates, such as a silicon germanium substrate, may also be used. It is understood that there may be other interlevel dielectric (ILD) layers arranged over the substrate 180, which are not illustrated in the interest of brevity. One or more electronic components, such as a transistor in a non-limiting example, may be arranged over/within the substrate 180. The MTJ stack and the first electrode 160 and the second electrode 170 may be coupled to the one or more electronic components. For example, the first electrode 160 (e.g., bottom electrode) may be in electrical communication with a drain of the transistor, and the second electrode 170 (e.g., top electrode) overlying the first electrode 160 may be electrically coupled to a bit line (BL) of a memory device. A contact may be used to electrically couple the drain with the first electrode, and another contact and/or other interconnects may be used to form other electrical connections for electrical communication. A source line (SL) may be in electrical communication with a source of the transistor, in a non-limiting example.

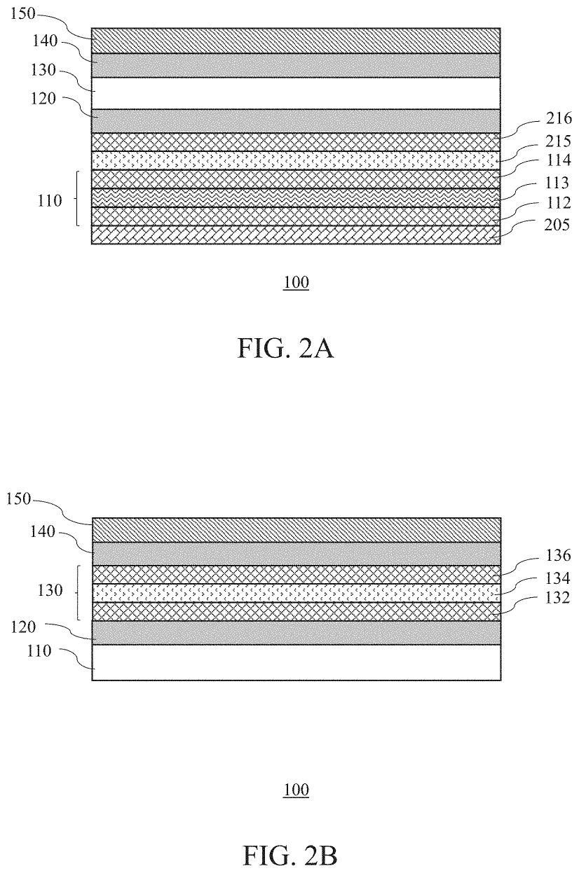

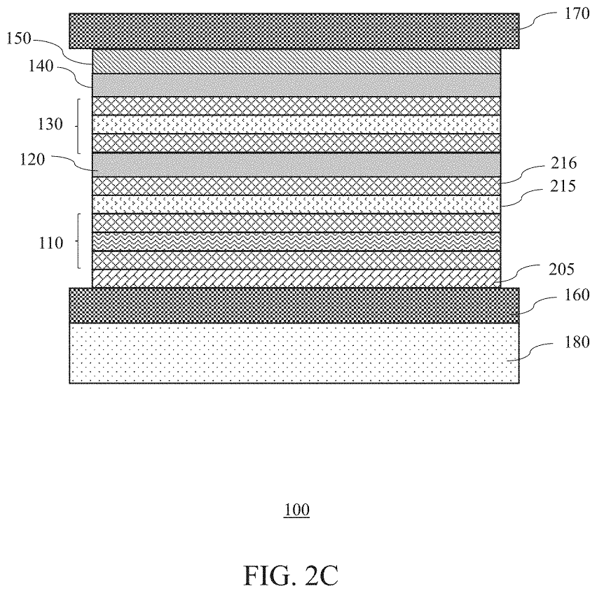

FIGS. 2A-2C show simplified cross-sectional views of embodiments of the device 100 in greater detail.

According to various non-limiting embodiments, the reference layer 110 may include a magnetic first pinned layer 112 and a magnetic second pinned layer 114, as illustrated in FIG. 2A. The first pinned layer 112 and the second pinned layer 114 may be magnetically hard layers. The first pinned layer 112 and/or the second pinned layer 114 may be formed of cobalt (Co), platinum (Pt), nickel (Ni), terbium (Tb), palladium (Pd), iron (Fe), boron (B), compounds thereof (e.g., cobalt platinum compounds) or combinations thereof. In a non-limiting embodiment, the first pinned layer 112 and/or the second pinned layer 114 may each include primarily cobalt and platinum. In a non-limiting embodiment, the first pinned layer 112 and/or the second pinned layer 114 may each include cobalt and platinum in an amount ranging from about 90 to about 100 weight percent, based on a total weight of the first pinned layer 112 or the second pinned layer 114, respectively. The different elements in the first pinned layer 112 and the second pinned layer 114 may be alloyed or formed of successive layers, so the first pinned layer 112 and the second pinned layer 114 may independently include a plurality of sub-layers in some embodiments. The first pinned layer 112 and the second pinned layer 114 may be magnetic, where the magnetic property of the combined first and second pinned layers 112 and 114 is the magnetic property for the reference layer 110 in embodiments with only two pinned layers, in a non-limiting example. The magnetic properties of the reference layer 110 may be utilized for memory purposes in the MTJ stack.

A coupling layer 113 may be arranged between the magnetic first pinned layer 112 and the magnetic second pinned layer 114. The coupling layer 113 may be a non-magnetic layer. The coupling layer 113 may include one or more materials, such as but not limited to, ruthenium (Ru), rhodium (Rh), iridium (Ir), or combinations thereof, in a non-limiting example. According to various non-limiting embodiments, the coupling layer 113 may provide an anti-ferromagnetic exchange between the first and second pinned layers 112 and 114 which may help reduce or compensate for stray magnetic field effects from the first and/or second pinned layers 112, 114. The use of such material(s), e.g. Ru, in the coupling layer 113 may produce strong paramagnetic anisotropy in the reference layer 110. In a non-limiting embodiment, the coupling layer 113 may include Ru in an amount ranging from about 50 to about 100 weight percent, or from about 80 to 100 weight percent, based on a total weight of the coupling layer 113.

According to various non-limiting embodiments, the MTJ stack may include a seed layer 205, on which the reference layer or stack 110 may be arranged. For example, the seed layer 205 may be arranged over the first electrode (e.g., bottom electrode), and the magnetic first pinned layer 112 may be arranged over the seed layer 205. The seed layer may be non-magnetic. The seed layer, for example, promotes crystalline texture to induce strong ferromagnetic properties in the reference layer 110 (e.g., magnetic first pinned layer 112). The seed layer may have a face-centered cubic (fcc) crystalline structure, in a non-limiting embodiment. The seed layer may include Pt, Ru, Ni, W, Cr, Ho, or alloys thereof, and which may be present as a single layer or as multiple layers, in a non-limiting example.

In some embodiments, the MTJ stack may further include a transition layer 215 and a polarizing layer 216. The transition layer 215 may be arranged over the reference layer 110, and the polarizing layer 216 may be arranged over the transition layer 215. In a non-limiting embodiment, the transition layer 215 overlies second pinned layer 114. The transition layer 215 may serve to break the crystalline structure from the underlying second pinned layer 114 (or other pinned layer, where more than two pinned layers are utilized), so the transition layer 215 may be amorphous in some embodiments. For example, the transition layer 215 may break the fcc texture from Co/Pt multilayers, so that the crystallinity can transit to body-centered cubic (bcc) crystallinity for subsequent overlying layers. The transition layer 215 may include a material comprising one or more of Ta, W, molybdenum (Mo), Tb, Fe, Co, or other elements, alloys thereof, combinations thereof, and optionally as one or more sub-layers, in some embodiments. The transition layer 215 may be thin enough such that a crystalline structure is not formed. In a non-limiting embodiment, the transition layer 215 may be non-magnetic, and the amorphous nature of the transition layer 215 allows for the non-magnetic characteristic even in embodiments that include iron, cobalt, or other materials that typically are magnetic. A transition layer which is magnetic may also be used in other embodiments.

As for the polarizing layer 216, it may be a magnetic. The polarizing layer 216 may incorporate a material including one or more of cobalt, iron, boron, or other elements, alloys thereof, combinations thereof, and optionally which may be present as a single layer or as multiple layers, in various non-limiting embodiments. The polarizing layer 216 may have a crystalline structure that is imparted to overlying layers in some embodiments, and may improve spin polarization efficiency in the MTJ stack. According to various non-limiting embodiments, the polarizing layer 216 may have a bcc crystalline structure, but other types of crystalline structures, such as fcc, are also possible. The polarizing layer 216 having a bcc crystallinity, for example, may have minimal lattice mismatch with a first tunneling barrier layer 120 having bcc crystallinity. According to various embodiments, the transition layer 215 may be relatively very thin in the MTJ stack, and as such the second pinned layer 114 and the polarizing layer 216 may serve as a combined ferromagnetic layer.

As illustrated, the first tunneling barrier layer 120 may be arranged over the polarizing layer 216, so the first tunneling barrier layer 120 also overlies the transition layer 215, the reference layer 110, and the seed layer 205. The free layer 130 may be arranged on top of the first tunneling barrier layer 120, followed by the second tunneling barrier layer 140 that serves to maximize the magnetic properties of the free layer 130. As illustrated in FIG. 2A, the capping layer 150 may be arranged over the seed layer 205, the reference layer 110, the transition layer 215, the polarizing layer 216, the first tunneling barrier layer 120, the free layer 130 and the second tunneling barrier layer 140.

As illustrated in FIG. 2B, the free layer 130 may include a first free sub-layer 132 and a second free sub-layer 136. Each of the first free sub-layer 132 and the second free sub-layer 136 may be a magnetic layer, and may optionally include free sub-layers. For example, the first free sub-layer 132 may include one, two, or more sub-layers, and the second free sub-layer 136 may include one, two, or more sub-layers. The first free sub-layer 132 and the second free sub-layer 136 may have the same composition, or they may have different compositions, and there may be more, less, or the same number of sub-layers in the first free sub-layer 132 and the second free sub-layer 136. The elements in the first free sub-layer 132 and the second free sub-layer 136 may be present as alloys or as layers of pure material or layers of alloys. In an exemplary embodiment, the first free sub-layer 132 and/or the second free sub-layer 136 may include a material comprising one or more of cobalt, iron, boron, or other elements, alloys thereof, or combinations thereof. For example, the first free sub-layer 132 and/or the second free sub-layer 136 may be one or more layers of CoFeB. The first free sub-layer 132 and the second free sub-layer 136 may be magnetically “soft” such that the spin transfer torque and the direction of magnetism can be changed. The first free sub-layer 132 and the second free sub-layer 136 may be magnetically anisotropic, and may have sufficient thermal stability to withstand processing temperatures without a loss of magnetism. The first free sub-layer 132 and the second free sub-layer 136 may have a thickness ranging from about 0.1 nm to about 1 nm, in a non-limiting example.

In some embodiments, an insertion layer 134 may be arranged between the first free sub-layer 132 and the second free sub-layer 136. The insertion layer 134 may be a non-magnetic layer. The insertion layer 134 may provide ferromagnetic coupling between the first free sub-layer 132 and the second free sub-layer 136 and may be thin enough to be amorphous. However, in some embodiments the insertion layer 134 may be crystalline. In some embodiments, the insertion layer 134 may include tantalum, molybdenum, tungsten, iron, or other components, as alloys or as individual elements.

FIG. 2C shows another embodiment of the MTJ stack of the device 100 in greater detail. As illustrated, the MTJ stack may be arranged between the first electrode 160 and the second electrode 170, and over the substrate 180. The MTJ stack may include the seed layer 205 arranged over the first electrode 170. The reference layer 110 as described with respect to FIG. 2A may be arranged over the seed layer 205. The MTJ stack may further include the transition layer 215 arranged over the reference layer 110, and the polarizing layer 216 arranged over the transition layer 215. The first tunneling barrier layer 120 may be arranged over the polarizing layer 216, and the free layer 130 as described with respect to FIG. 2B may be arranged over the first tunneling barrier layer 120. The MTJ stack may further include the second tunneling barrier layer 140 arranged over the free layer 130, and the capping layer 150 arranged over the second tunneling barrier layer 140.

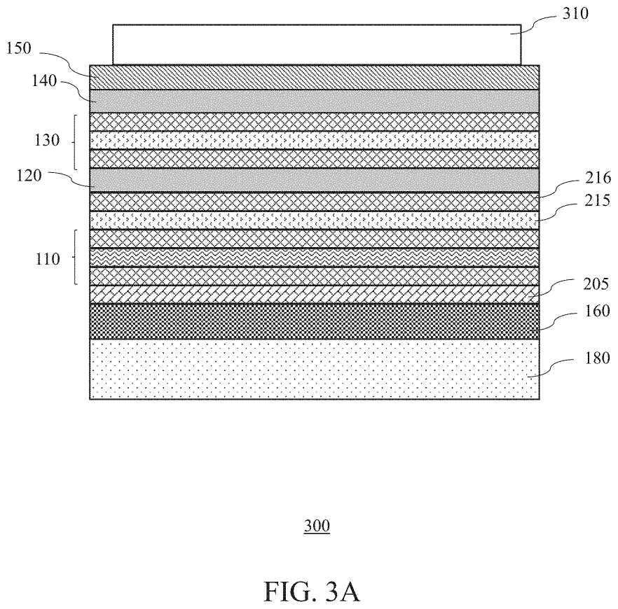

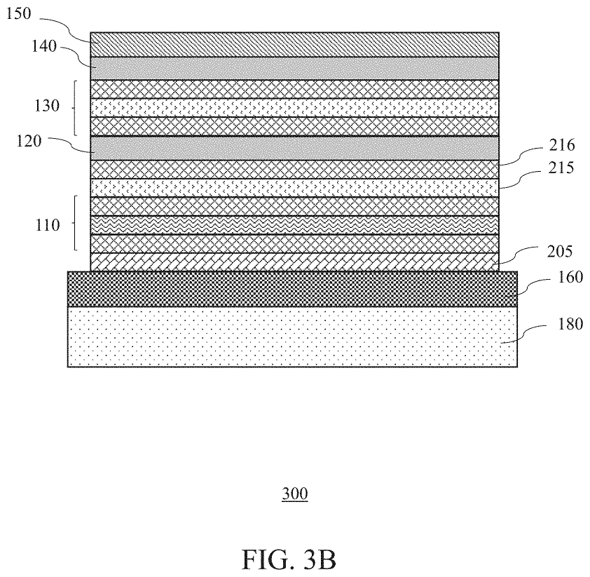

FIGS. 3A-3B show simplified cross-sectional views of an embodiment of a process 300 for forming a device. The device may include an MTJ device or stack. The device formed, for example, is similar or the same as that shown and described in FIGS. 1A-1D and FIGS. 2A-2C. As such, common elements may not be described or described in detail.

In various non-limiting embodiments, a wafer or substrate 180 may be provided. The substrate may be a semiconductor substrate, such as a silicon substrate. Other types of semiconductor substrates, such as a silicon germanium substrate, may also be used. In the interest of brevity, the processing of the substrate 180 to form one or more electronic components and interlevel dielectric (ILD) layer is not illustrated. In a non-limiting embodiment, the MTJ stack may be arranged or embedded in the ILD layer.

In a non-limiting embodiment, a first electrode 160 may be formed over the substrate. The MTJ stack may be formed over the substrate 180 and the first electrode 160. The MTJ stack may be formed by depositing the various layers of the MTJ stack, where the various layers within the MTJ stack may be formed by sputtering, ion beam deposition, or other techniques using the appropriate materials. Forming the MTJ stack may include forming the seed layer 205 over the first electrode 160, forming the reference layer 110 over the seed layer 205, forming the transition layer 215 over the reference layer 110, forming the polarizing layer 216 over the transition layer 215, forming the first tunneling barrier layer 120 over the polarizing layer 216, forming the free layer 130 over the first tunneling barrier layer 120, forming the second tunneling barrier layer 140 over the free layer 130, and/or forming the capping layer 150 over the second tunneling barrier layer 140. In some embodiments, the free layer 130 may be sputtered on top of the first tunneling barrier layer 120, followed by the second tunneling barrier layer 140 which serves to maximize the magnetic properties of the free layer 130. In other embodiments, the second tunneling barrier layer 140 may not be required or formed.

According to various non-limiting embodiments, the capping layer 150 may be formed by sputtering the material comprising the rare earth element(s) (e.g., Ho) in an argon environment with a gas flow rate of about 2 standard cubic centimeters per minute (SCCM) at a sputter power of about 50 watts and a chamber pressure of about (1*e)−8, in a non-limiting example. Other deposition techniques or parameters may also be used.

The capping layer 150 may be annealed before other overlying layers are deposited, or the capping layer 150 may be annealed after the overlying layers are deposited. For example, annealing may drive elements, such as boron, away from the free layer 130 leading to a high TMR ratio, while reducing the series resistance. In a non-limiting embodiment, the anneal may be at about 350 degrees Celsius (° C.) or higher for a time period ranging from at least about 30 minutes to about 1 hour or more, in a non-limiting example, but other annealing conditions may also be used.

The capping layer 150 may readily scavenge oxygen from the second tunneling barrier layer 140 (e.g., MgO), forming a rare earth metal oxide with electrical conductivity higher than the second tunneling barrier layer 140. The electrical conductivity of the rare earth metal oxide may be at least about 5×10⁹ Ω⁻¹·cm⁻¹ at about 400° C., in a non-limiting example.

The area where the MTJ stack is to be formed may then be lithographically protected using a patterned mask 310, as illustrated in FIG. 3A. The exposed portions may be removed with appropriate etchants, forming the MTJ stack over the substrate 180 and the first electrode 160, as illustrated in FIG. 3B. As described, patterning may be performed after annealing, however, patterning may be performed prior to annealing in other embodiments.

It has been found from testings performed that further increasing the thickness of the capping layer 150 may lead to further reduction in series resistance in the MTJ stack, i.e. an inverse relationship between the thickness of the capping layer and the series resistance in the MTJ stack. However, the TMR did not improve beyond a certain thickness of the capping layer 150, illustrating the ability of such rare earth elements to control the oxygen stoichiometry ratio in the second tunneling barrier layer.

The MTJ device according to various embodiments of the present invention which is arranged with the capping layer incorporating one or more materials including one or more rare earth elements, and arranged over the second tunneling barrier layer may be able to increase TMR by about 20%, while simultaneously reducing the RA product by 1.5 Ω·μm², in a non-limiting example.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A semiconductor device, comprising:
a magnetic tunnel junction (MTJ) stack, the MTJ stack comprising:
a reference layer comprising a magnetic layer;
a first tunneling barrier layer arranged over the reference layer;
a free layer comprising a magnetic layer arranged over the first tunneling barrier layer;
and
a capping layer arranged over the reference layer, the first tunneling barrier layer and the free layer, wherein the capping layer is a non-magnetic layer; and wherein the capping layer comprises a rare earth element.

2. The semiconductor device of claim 1, further comprising a second tunneling barrier layer arranged between the free layer and the capping layer, wherein the capping layer contacts the second tunneling barrier layer.

3. The semiconductor device of claim 2, wherein the first tunneling barrier layer and the second tunneling barrier layer each comprises a dielectric oxide layer.

4. The semiconductor device of claim 1, wherein the rare earth element comprises La, Pr, Nd, Sm, Eu, Gd, Ho, or alloys thereof.

5. The semiconductor device of claim 1, wherein the capping layer comprises a conductive metal oxide layer formed from the rare earth element.

6. The semiconductor device of claim 1, wherein the capping layer comprises a rare-earth transition metal alloy.

7. The semiconductor device of claim 1, wherein the reference layer comprises a magnetic first pinned layer and a magnetic second pinned layer, and wherein the reference layer further comprises a coupling layer arranged between the first pinned layer and the second pinned layer, wherein the coupling layer is a non-magnetic layer.

8. The semiconductor device of claim 8, wherein the free layer comprises a first free sub-layer and a second free sub-layer, and wherein the free layer further comprises an insertion layer arranged between the first free sub-layer and the second free sub-layer, wherein the insertion layer is a non-magnetic layer.

9. The semiconductor device of claim 1, wherein the capping layer comprises the rare earth element in an amount ranging from about 30 to about 100 weight percent, based on a total weight of the capping layer.

10. The semiconductor device of claim 1, wherein the capping layer comprises Ho in an amount ranging from about 30 to about 100 weight percent, based on a total weight of the capping layer.

11. The semiconductor device of claim 1, wherein the capping layer has a thickness of about 1.5 nm or less.

12. The semiconductor device of claim 1, further comprising a first electrode and a second electrode; wherein the MTJ stack is arranged between the first electrode and the second electrode.

13. The semiconductor device of claim 12, wherein the capping layer contacts the second electrode.

14. A method of forming a magnetic tunnel junction stack, comprising:
forming a reference layer comprising a magnetic layer;
forming a first tunneling barrier layer over the reference layer;
forming a free layer comprising a magnetic layer over the first tunneling barrier layer; and
forming a capping layer arranged over the reference layer, the first tunneling barrier layer and the free layer, wherein the capping layer is a non-magnetic layer; and wherein the capping layer comprises a rare earth element.

15. The method of claim 14, further comprising forming a second tunneling barrier layer between the free layer and the capping layer, wherein the capping layer contacts the second tunneling barrier.

16. The method of claim 14, wherein the rare earth element comprises La, Pr, Nd, Sm, Eu, Gd, Ho, alloys thereof, or combinations thereof.

17. The method of claim 14, wherein the capping layer comprises a rare-earth transition metal alloy.

18. The method of claim 14, wherein the capping layer comprises the rare earth element in an amount ranging from about 30 to about 100 weight percent, based on a total weight of the capping layer.

19. The method of claim 14, wherein the capping layer has a thickness of about 1.5 nm or less.
